(19) United States
(12) Patent Application Publication
(10) Pub. No.: US 2025/0158580 A1
(43) Pub. Date: May 15, 2025

(54) AMPLIFICATION CIRCUIT

(71) Applicant: RichWave Technology Corp., Taipei City (TW)

(72) Inventors: Tien-Yun Peng, Taipei City (TW); Ching-Wen Hsu, Taipei City (TW); Chih-Sheng Chen, Taipei City (TW)

(73) Assignee: RichWave Technology Corp., Taipei City (TW)

(21) Appl. No.: 18/391,681

(22) Filed: Dec. 21, 2023

(30) Foreign Application Priority Data
Nov. 14, 2023 (TW) 112143877

(51) Int. Cl. H03F 3/195; H03F 1/08

(52) U.S. Cl. CPC H03F 3/195; H03F 1/086; H03F 2200/387; H03F 2200/451

(57) ABSTRACT

An amplification circuit includes a radio-frequency input terminal, a radio-frequency output terminal, a first amplification stage circuit, a second amplification stage circuit, and a variable impedance path. The radio-frequency input terminal is used to receive a radio-frequency signal. The radio-frequency output terminal is used to output the amplified radio-frequency signal. The first amplification stage circuit is coupled to the radio-frequency input terminal and the radio-frequency output terminal. The second amplification stage circuit is coupled to the radio-frequency input terminal and the radio-frequency output terminal. The variable impedance path is coupled to the first amplification stage circuit and the second amplification stage circuit. When the second amplification stage circuit is enabled, the variable impedance path has a low impedance. When the second amplification stage circuit is disabled, the variable impedance path has a high impedance.

### TECHNICAL FIELD

The disclosure is related to an amplification circuit, and more particularly, an amplification circuit capable of reducing a voltage difference of transistors of two amplification stage circuits for improving the quality of transceiving signals.

### BACKGROUND

As the application of wireless communications broadens, radio-frequency circuits are also widely used in various electronic devices to transmit and receive wireless signals. In current radio-frequency circuits, when two amplification stage circuits, such as two stages of low noise amplifiers (LNAs), are used to transmit, receive and amplify signals, there is a voltage difference between the voltages (e.g. the drain-source voltages) of the transistors of the two amplification stage circuits in a high current mode. For example, the voltage difference may be as high as 50 millivolts. According to actual measurements, since it is difficult to reduce the voltage difference, the operation timings of the two amplification stage circuits will be different, resulting in unwanted dynamic error vector magnitude (DEVM) problems, which will reduce the linearity of the circuit and deteriorate the performance of transceiving signals. A suitable solution to deal with this problem is still in need in the field.

### SUMMARY

An embodiment provides an amplification circuit including a radio-frequency input terminal, a radio-frequency output terminal, a first amplification stage circuit, a second amplification stage circuit, and a variable impedance path. The radio-frequency input terminal is configured to receive a radio-frequency signal. The radio-frequency output terminal is configured to output an amplified radio-frequency signal. The first amplification stage circuit comprises a first terminal coupled to the radio-frequency input terminal, a second terminal coupled to the radio-frequency output terminal, and a third terminal. The second amplification stage circuit comprises a first terminal coupled to the radio-frequency input terminal, a second terminal coupled to the radio-frequency output terminal, an internal node, and a third terminal coupled to the internal node. The variable impedance path is coupled to the internal node, and comprises a first terminal coupled to the third terminal of the first amplification stage circuit, and a second terminal coupled to the third terminal of the second amplification stage circuit. The variable impedance path has a low impedance when the variable impedance path is enabled, and the variable impedance path has a high impedance and the internal node is a high impedance node when the variable impedance path is disabled.

Another embodiment provides an amplification circuit including a radio-frequency input terminal, a radio-frequency output terminal, a first amplification stage circuit, a second amplification stage circuit and a switch. The radio-frequency input terminal is configured to receive a radio-frequency signal. The radio-frequency output terminal is configured to output an amplified radio-frequency signal. The first amplification stage circuit comprises a first transistor and a second transistor coupled in series, where a first terminal of the first transistor is coupled to the radio-frequency output terminal, and a control terminal of the second transistor is coupled to the radio-frequency input terminal. The second amplification stage circuit comprises a third transistor and a fourth transistor coupled in series, where a first terminal of the third transistor is coupled to the radio-frequency output terminal, and a control terminal of the fourth transistor is coupled to the radio-frequency input terminal. The switch comprises a first terminal coupled to a node between the first transistor and the second transistor, and a second terminal coupled to a node between the third transistor and the fourth transistor.

### BRIEF DESCRIPTION OF THE DRAWINGS

FIG. 1 illustrates an amplification circuit according to an embodiment.

FIG. 2 illustrates an amplification circuit according to another embodiment.

FIG. 3 illustrates an amplification circuit coupled to a load circuit according to another embodiment.

FIG. 4 illustrates an amplification circuit according to another embodiment.

FIG. 5 illustrates an amplification circuit according to another embodiment.

FIG. 6 illustrates an amplification circuit according to another embodiment.

FIG. 7 illustrates an amplification circuit according to another embodiment.

FIG. 8 illustrates an amplification circuit according to another embodiment.

FIG. 9 illustrates an amplification circuit according to another embodiment.

FIG. 10 illustrates an amplification circuit according to another embodiment.

### DETAILED DESCRIPTION

Below, exemplary embodiments will be described in detail with reference to accompanying drawings so as to be easily realized by a person having ordinary knowledge in the art. The inventive concept may be embodied in various forms without being limited to the exemplary embodiments set forth herein. Descriptions of well-known parts are omitted for clarity, and like reference numerals refer to like elements throughout.

In the text, each transistor can include a first terminal, a second terminal and a control terminal. When two transistors are mentioned to be coupled in series, a second terminal of one transistor can be coupled to a first terminal of the other one transistor. In the text, when it mentions two voltages are equal, a difference of the two voltages is lower than 10% of each of the two voltages. In the text, when a component is turned off or disabled, the component can be in an OFF state. In the text, when a component is turned on or enabled, the component can be in an ON state. In the text, AC means alternating current, and DC means direct current.

FIG. 1 illustrates an amplification circuit 100 according to an embodiment. The amplification circuit 100 can include a radio-frequency input terminal RFIN, a radio-frequency output terminal RFOUT, a first amplification stage circuit 110, a second amplification stage circuit 120 and a variable impedance path 130. The radio-frequency input terminal RFIN can receive a radio-frequency signal S1. The radio-frequency output terminal RFOUT can output a radio-frequency signal S2, i.e. the amplified radio-frequency signal S1. The radio-frequency signal S1 and the radio-frequency signal S2 can be AC signals carrying data of wireless communications.

The first amplification stage circuit 110 can include a first terminal, a second terminal and a third terminal, where the first terminal can be coupled to the radio-frequency input terminal RFIN, and the second terminal can be coupled to the radio-frequency output terminal RFOUT.

The second amplification stage circuit 120 can include a first terminal, a second terminal, a third terminal and an internal node, where the first terminal can be coupled to the radio-frequency input terminal RFIN, and the second terminal can be coupled to the radio-frequency output terminal RFOUT.

The variable impedance path 130 can include a first terminal and a second terminal, where the first terminal can be coupled to the third terminal of the first amplification stage circuit 110, and the second terminal can be coupled to the third terminal of the second amplification stage circuit 120. The internal node of the second amplification stage circuit 120 (e.g. the internal node NH in FIG. 1) coupled to the third terminal of the second amplification stage circuit 120, and the variable impedance path 130 can be coupled to the internal node.

The variable impedance path 130 can have a low impedance when the second amplification stage circuit 120 is enabled, and the internal node NH is not a high impedance node. The variable impedance path 130 can have a high impedance when the second amplification stage circuit 120 is disabled, and the internal node NH is a high impedance node. A reference voltage Vr1 of FIG. 1 can be a power-supply voltage or a predetermined high reference voltage. In this embodiment, when the second amplification stage circuit 120 is disabled, the internal node NH is floating, the variable impedance path 130 can have a high impedance (e.g. DC high resistance), so the internal node NH can be maintained as a high impedance node. When the second amplification stage circuit 120 is enabled, the internal node NH can be converted from a floating node to a non-floating node, so the internal node NH is not a high impedance node. However, when the second amplification stage circuit 120 is enabled, a voltage of the internal node NH can be determined according to an internal circuit structure and/or related parameters of the second amplification stage circuit 120, so the voltage of the internal node NH may be different from an expected voltage (e.g. internal voltage of the third terminal of the first amplification stage circuit 110). Hence, the operation timings of the two amplification stage circuits 110 and 120 may be different, affecting the dynamic error vector magnitude (DEVM) of the amplification circuit 100. Hence, in this embodiment, the variable impedance path 130 can be further controlled to have a low impedance, so the voltage of the internal node NH is close to or equal to the voltage of the third terminal of the first amplification stage circuit 110, making the operation timings of the two amplification stage circuits 110 and 120 close to or equal to one another, reducing the unwanted dynamic error vector magnitude (DEVM), improving the linearity of the circuit, and improving the quality of transceiving signals. Moreover, since the variable impedance path 130 can have a low impedance (e.g. DC low resistance), so a DC voltage of the internal node NH can be defined by a voltage of the third terminal of the first amplification stage circuit 110. Moreover, when the first amplification stage circuit 110 is enabled, and the second amplification stage circuit 120 is disabled, the radio-frequency signal S1 can be amplified by the first amplification stage circuit 110 to generate the radio-frequency signal S2, and the amplification circuit 100 can be in a low current mode. When the first amplification stage circuit 110 and the second amplification stage circuit 120 are enabled, the radio-frequency signal S1 can be amplified by the first amplification stage circuit 110 and the second amplification stage circuit 120 together to generate the radio-frequency signal S2, and the amplification circuit 100 can be in a high current mode.

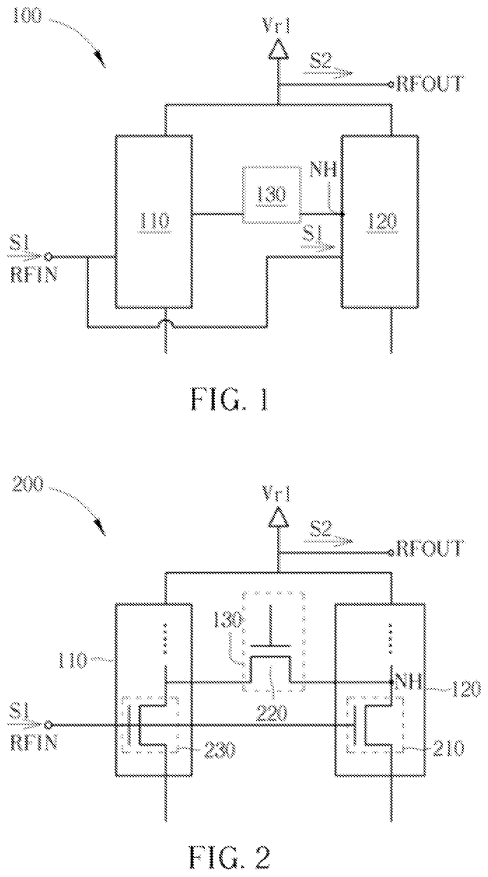

FIG. 2 illustrates a 200 according to another embodiment. Compared with FIG. 1, the second amplification stage circuit 120 of FIG. 2 can further include a transistor 210. The variable impedance path 130 can further include a transistor 220 coupled to a first terminal (e.g. drain terminal) of the transistor 210. The first amplification stage circuit 110 can further include a transistor 230. The transistor 220 of the variable impedance path 130 can be coupled to a first terminal (e.g. drain terminal) of the transistor 230. In FIG. 2, when the second amplification stage circuit 120 is disabled, the transistors 210 and 220 can be turned off, and the internal node NH is a high impedance node. When the second amplification stage circuit 120 is enabled, the transistors 210 and 220 can be turned on, and the internal node NH is not a high impedance node. In this embodiment, when the second amplification stage circuit 120 is disabled, the transistors 210 and 220 can be turned off, the internal node NH can be floating, the variable impedance path 130 can have a high impedance (e.g. DC high resistance), so the internal node NH is maintained as a high impedance node. When the second amplification stage circuit 120 is enabled, the internal node NH can be converted from a floating node to a non-floating node, so the internal node NH is not a high impedance node. Moreover, since the transistor 220 is turned on, the variable impedance path 130 can have a low impedance (e.g. DC low resistance), so a DC voltage of the internal node NH can be defined by a voltage of the first terminal of the transistor 230. Moreover, when the first amplification stage circuit 110 is enabled, and the second amplification stage circuit 120 is disabled, the radio-frequency signal S1 can be amplified by the first amplification stage circuit 110 to generate the radio-frequency signal S2, and the amplification circuit 200 can be in the low current mode. When the first amplification stage circuit 110 and the second amplification stage circuit 120 are enabled, the radio-frequency signal S1 can be amplified by the first amplification stage circuit 110 and the second amplification stage circuit 120 together to generate the radio-frequency signal S2, and the amplification circuit 200 can be in the high current mode.

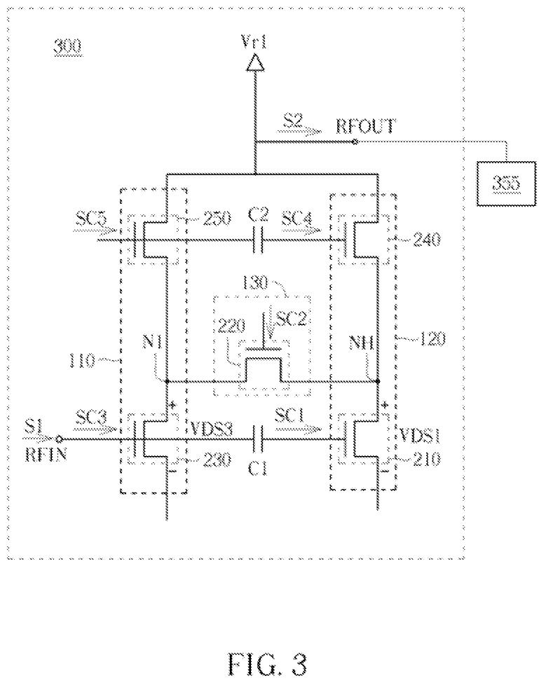

FIG. 3 illustrates an amplification circuit 300 coupled to a load circuit 355 according to another embodiment. Compared with FIG. 1, the second amplification stage circuit 120 in FIG. 3 can further include a transistor 210 and a transistor 240. The transistor 210 and the transistor 240 can be coupled in series. When the transistor 210 and the transistor 240 are turned on, the second amplification stage circuit 120 is enabled. When the transistor 210 and the transistor 240 are turned off, the second amplification stage circuit 120 is disabled. For example, control signals SC1 and SC4 can turn on and turn off the transistors 210 and 240 respectively. The control signals SC1 and SC4 can be DC bias signals. Optionally, signal levels of the control signals SC1 and SC4 can be equal.

The first amplification stage circuit 110 can further include a transistor 230 and a transistor 250. The transistor 230 and the transistor 250 can be coupled in series. When the transistor 230 and the transistor 250 are turned on, the first amplification stage circuit 110 is enabled. When the transistor 230 and the transistor 250 are turned off, the first amplification stage circuit 110 is disabled. For example, control signals SC3 and SC5 can turn on and turn off the transistors 230 and 250 respectively. The control signals SC3 and SC5 can be DC bias signals. Optionally, signal levels of the control signals SC3 and SC5 can be equal.

Since control signals SC1, SC3, SC4 and SC5 can be DC bias signals, and the radio-frequency signal S1 and the radio-frequency signal S2 can be AC signals, so the control signals SC1, SC3, SC4 and SC5 can control the transistors 210, 230, 240 and 250 to be turned on or turned off respectively while the radio-frequency signal S1 and the radio-frequency signal S2 are accessed. According to embodiments, a capacitor C1 and/or a capacitor C2 can be disposed optionally to block DC signal to turn on/turn off the transistor respectively. In an embodiment, the control terminals of the transistor 240 and the transistor 250 can be coupled to a reference voltage terminal through a capacitor (not shown) to provide a common AC ground path for the control terminals of the transistor 240 and the transistor 250. In another embodiment, the control terminals of the transistor 240 and the transistor 250 can be electrically disconnected, two AC ground paths can be provided for the control terminals of the transistor 240 and the transistor 250 respectively, and the capacitor C2 can be omitted.

As shown in FIG. 3, the radio-frequency input terminal RFIN can be coupled to a control terminal of the transistor 230, and the radio-frequency input terminal RFIN can be coupled to a control terminal of the transistor 210.

The radio-frequency output terminal RFOUT can be coupled to the load circuit 355. When the load circuit 355 has a first load, the second amplification stage circuit 120 can be enabled. When the load circuit 355 has a second load, the second amplification stage circuit 120 can be disabled. The first load and the second load can be different. For example, the first load can be larger than the second load. In other words, the second amplification stage circuit 120 can be enabled or disabled corresponding to different loads. In FIG. 3, the size of the transistor 240 and the size of the transistor 250 can be different to provide corresponding resistances for different loads. Moreover, when the first amplification stage circuit 110 is enabled, and the second amplification stage circuit 120 is disabled, the radio-frequency signal S1 can be amplified by the first amplification stage circuit 110 to generate the radio-frequency signal S2, and the amplification circuit 300 can be in the low current mode. When the first amplification stage circuit 110 and the second amplification stage circuit 120 are enabled, the radio-frequency signal S1 can be amplified by the first amplification stage circuit 110 and the second amplification stage circuit 120 together to generate the radio-frequency signal S2, and the amplification circuit 300 can be in the high current mode. When the radio-frequency output terminal RFOUT is coupled to different loads, the amplification circuit 300 can be operated in the high current mode and the low current mode for different loads. For example, when the radio-frequency output terminal RFOUT is coupled to the first load, the amplification circuit 300 can be in one of the high current mode and the low current mode. When radio-frequency output terminal RFOUT is coupled to the second load, the amplification circuit 300 can be in the other one of the high current mode and the low current mode.

In FIG. 3, the variable impedance path 130 can include a transistor 220. The transistor 220 can include a first terminal, a second terminal and a control terminal, where the first terminal can be coupled to the node N1 between the transistor 230 and the transistor 250, the second terminal can be coupled to the internal node NH between the transistor 210 and the transistor 240, and the control terminal can receive the control signal SC2 to turn on or turn off the transistor 220.

When the amplification circuit 300 is in the low current mode, the second amplification stage circuit 120 can be disabled, and the internal node NH can be a high impedance node. Since the transistors 210, 220 and 230 can be turned off at this time, the internal node NH can be floating, and the impedances looked from the internal node NH towards the transistors 210, 220 and 230 can be high impedances.

When the amplification circuit 300 is in the high current mode, the second amplification stage circuit 120 can be enabled, the internal node NH can change from floating to non-floating, and the internal node NH is not a high impedance node. However, in the high current mode, the voltage of the internal node NH can be mainly determined according to an internal circuit structure and/or related parameters in the second amplification stage circuit 120, hence the voltage of the internal node NH may be different from an expected voltage. For example, the voltages of the node N1 and the internal node NH can be different because (1) the operation currents of the two amplification stages are different, (2) the voltage difference between the first terminal and the second terminal of the transistor 210 is different from that of the transistor 230 (i.e. VD S1≠VDS3), and/or (3) the voltage difference between the first terminal and the second terminal of the transistor 240 is different from that of the transistor 250. Hence, the operation timings of the two amplification stage circuits 110 and 120 can be different, affecting the dynamic error vector magnitude (DEVM) of the amplification circuit 300. Hence, in this embodiment, the transistor 220 can be turned on to control the variable impedance path 130 to have a low impedance, so the voltage of the node N1 (i.e. the first terminal of the transistor 230) can be close to or equal to the voltage of the internal node NH (i.e. the first terminal of the transistor 210), making the operation timings of the two amplification stage circuits 110 and 120 close to or equal to one another, reducing the unwanted dynamic error vector magnitude (DEVM), improving the linearity of the circuit, and improving the quality of transceiving signals. Moreover, in the high current mode, the radio-frequency signal S1 is not only amplified by the first amplification stage circuit 110 and the second amplification stage circuit 120 respectively, but part of the radio-frequency signal amplified by the transistor 230 of the first amplification stage circuit 110 is also transmitted to the internal node NH of the second amplification stage circuit 120 through the variable impedance path 130 to generate a part of the radio-frequency signal S2, further improving the quality of transceiving signals.

When the second amplification stage circuit 120 is enabled by the control signals SC1 and SC4, the transistor 220 can be turned on by the control signal SC2. When the second amplification stage circuit 120 is disabled by the control signals SC1 and SC4, the transistor 220 can be turned off by the control signal SC2. As shown in FIG. 3, the control terminal of the transistor 220 can receive the control signal SC2, and the control signal SC2 can turn on and turn off the transistor 220.

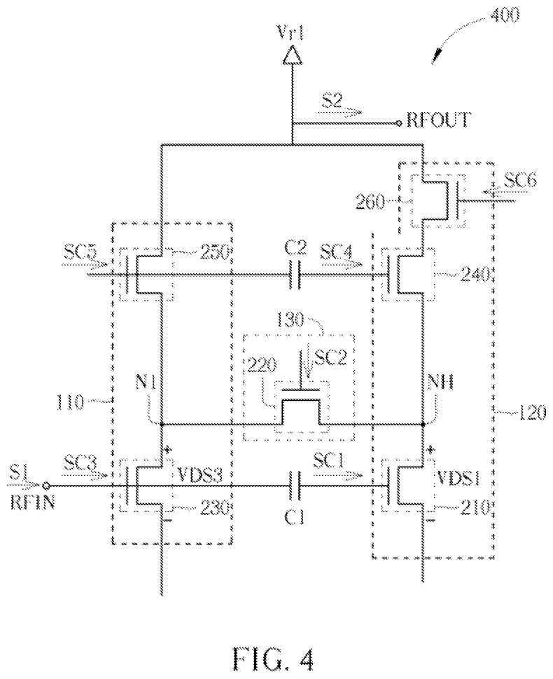

If the abovementioned transistors are field effect transistors, the first terminal, second terminal and control terminal of a transistor can be a drain terminal, a source terminal and a gate terminal. If the abovementioned transistors are bipolar junction transistors, the first terminal, second terminal and control terminal of a transistor can be a collector terminal, an emitter terminal and a base terminal. FIG. 4 illustrates an amplification circuit 400 according to another embodiment. Compared with FIG. 3, the second amplification stage circuit 120 in FIG. 4 can further include a transistor 260. The transistor 260 and the transistor 240 can be coupled in series. The transistor 240 can be coupled between the transistor 210 and the transistor 260. When the second amplification stage circuit 120 is enabled, the transistor 260 can be turned on. When the second amplification stage circuit 120 is disabled, the transistor 260 can be turned off. A control terminal of the transistor 260 can receive a control signal SC6 to turn on and turn off the transistor 260. The transistor 260 can be controlled to further ensure the enabled state/the disabled state of the second amplification stage circuit 120. Moreover, when the first amplification stage circuit 110 is enabled by the control signals SC3 and SC5, and the second amplification stage circuit 120 is disabled by the control signals SC1, SC4 and SC6, the amplification circuit 400 can be in the low current mode. When the first amplification stage circuit 110 is enabled by the control signals SC3 and SC5, and the second amplification stage circuit 120 is enabled by the control signals SC1, SC4 and SC6, the amplification circuit 400 can be in the high current mode.

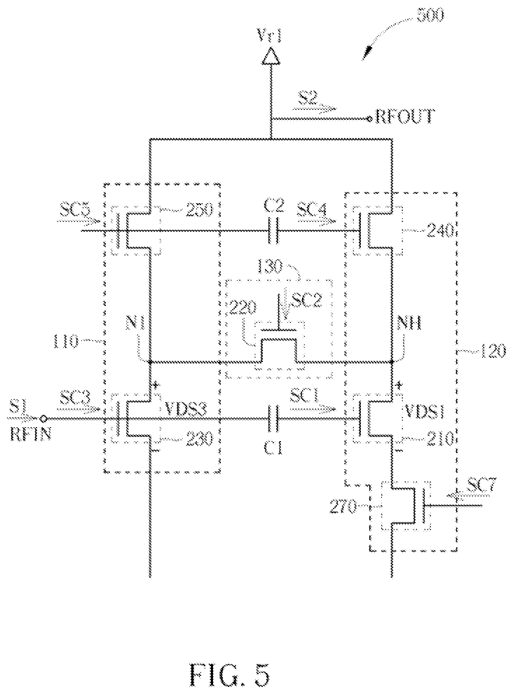

FIG. 5 illustrates an amplification circuit 500 according to another embodiment. Compared with FIG. 3, the second amplification stage circuit 120 in FIG. 4 can further include a transistor 270. The transistor 270 and the transistor 210 can be coupled in series. The transistor 210 can be coupled between the transistor 240 and the transistor 270. When the second amplification stage circuit 120 is enabled, the transistor 270 can be turned on. When the second amplification stage circuit 120 is disabled, the transistor 270 can be turned off. A control terminal of the transistor 270 can receive a control signal SC7 to turn on and turn off the transistor 270. The transistor 270 can be controlled to further ensure the enabled state/the disabled state of the second amplification stage circuit 120. Moreover, when the first amplification stage circuit 110 is enabled by the control signals SC3 and SC5, and the second amplification stage circuit 120 is disabled by the control signals SC1, SC4 and SC7, the amplification circuit 500 can be in the low current mode. When the first amplification stage circuit 110 is enabled by the control signals SC3 and SC5, and the second amplification stage circuit 120 is enabled by the control signals SC1, SC4 and SC7, the amplification circuit 500 can be in the high current mode.

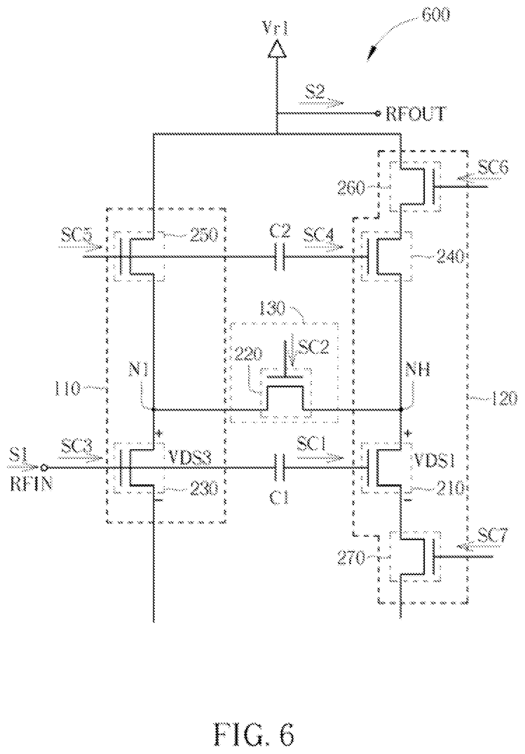

FIG. 6 illustrates an amplification circuit 600 according to another embodiment. Compared with FIG. 3, the second amplification stage circuit 120 in FIG. 6 can further include the transistor 260 and the transistor 270. The transistor 260 and the transistor 240 can be coupled in series. The transistor 270 and the transistor 210 can be coupled in series. The transistor 210 and the transistor 240 can be coupled between the transistor 260 and the transistor 270. When the second amplification stage circuit 120 is enabled, the transistor 260 and the transistor 270 can be turned on. When the second amplification stage circuit 120 is disabled, the transistor 260 and the transistor 270 can be turned off. Similar to FIG. 4 and FIG. 5, the control signal SC6 can turn on and turn off the transistor 260, and the control signal SC7 can turn on and turn off the transistor 270. The transistor 260 and the transistor 270 can be disposed and used to further ensure the enabled state/the disabled state of the second amplification stage circuit 120. Moreover, when the first amplification stage circuit 110 is enabled by the control signals SC3 and SC5, and the second amplification stage circuit 120 is disabled by the control signals SC1, SC4, SC6 and SC7, the amplification circuit 600 can be in the low current mode. When the first amplification stage circuit 110 is enabled by the control signals SC3 and SC5, and the second amplification stage circuit 120 is enabled by the control signals SC1, SC4, SC6 and SC7, the amplification circuit 600 can be in the high current mode. In another embodiment, in order to have the operation timings of the first amplification stage circuit 110 to be closer to the operation timings of the second amplification stage circuit 120, when the amplification circuit 600 is in the low current mode, the transistors 230 and 250 in the first amplification stage circuit 110 and the transistors 210 and 240 in the second amplification stage circuit 120 can be turned on by the control signals SC3, SC5, SC1 and SC4, and the transistors 260 and 270 can be turned off by the control signals SC6 and SC7, where the second amplification stage circuit 120 can still be disabled, and the unwanted dynamic error vector magnitude (DEVM) is further reduced.

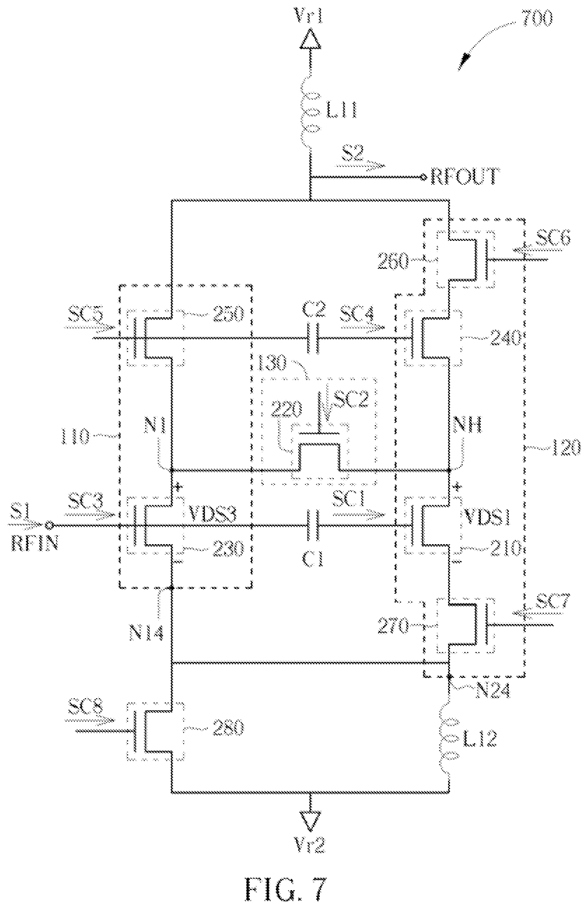

FIG. 7 illustrates an amplification circuit 700 according to another embodiment. Compared with FIG. 6, the amplification circuit 700 in FIG. 7 can further include a transistor 280. The first amplification stage circuit 110 can further include a fourth terminal such as a node N14, and the second amplification stage circuit 120 can further include a fourth terminal such as a node N24. The transistor 280 can include a first terminal, a second terminal and a control terminal, where the first terminal can be coupled to the fourth terminals of the first amplification stage circuit 110 and the second amplification stage circuit 120, and the second terminal can receive a reference voltage Vr2. The reference voltage Vr2 can be a ground voltage or a predetermined low reference voltage. When the second amplification stage circuit 120 is enabled, the transistor 280 can be turned on. When the second amplification stage circuit 120 is disabled, the transistor 280 can be turned off. The control terminal of the transistor 280 can receive a control signal SC8 to turn on and turn off the transistor 280. As shown in FIG. 7, optionally, the amplification circuit 700 can include inductors L11 and L12 for signal modulation and impedance matching. The transistor 280 and the inductor L12 can be coupled in parallel, where the first terminal of the transistor 280 can be coupled to a first terminal of the inductor L12, and the second terminal of the transistor 280 can be coupled to a second terminal of the inductor L12. For example, when the amplification circuit 700 is in the high current mode and the second amplification stage circuit 120 is enabled, the transistor 280 can be in one of an ON state and an OFF state. When the amplification circuit 700 is in the low current mode and the second amplification stage circuit 120 is disabled, the transistor 280 can be in the other one of the ON state and the OFF state. In this way, the amplification circuit 700 can have better impedance matching.

The abovementioned control signals SC1, SC2, SC3, SC4, SC5, SC6, SC7 and SC8 can be DC bias signals and can be used to turn on and turn off the transistors 210, 220, 230, 240, 250, 260, 270 and 280 respectively. Optionally, the signal levels of the control signals SC3 and SC5 can be equal. Optionally, the signal levels of the control signals SC1, SC4, SC6 and SC7 can be equal. In another embodiment, optionally, the signal levels of the control signals SC1, SC3, SC4 and SC5 can be equal, and the signal levels of the control signals SC6 and SC7 can be equal.

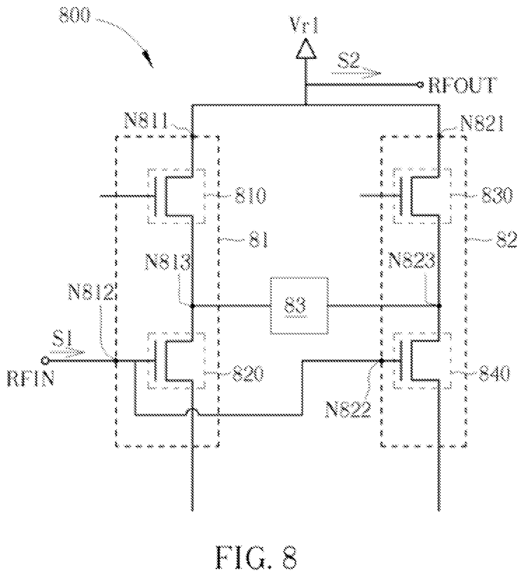

FIG. 8 illustrates an amplification circuit 800 according to another embodiment. The amplification circuit 800 can include the radio-frequency input terminal RFIN, the radio-frequency output terminal RFOUT, a first amplification stage circuit 81, a second amplification stage circuit 82 and a switch 83. The radio-frequency input terminal RFIN can receive the radio-frequency signal S1. The radio-frequency output terminal RFOUT can output the amplified radio-frequency signal, i.e. the radio-frequency signal S2.

The first amplification stage circuit 81 can include a transistor 810 and a transistor 820. The transistor 810 and the transistor 820 can be coupled in series. A first terminal of the transistor 810 can be coupled to the radio-frequency output terminal RFOUT, and a control terminal of the transistor 820 can be coupled to the radio-frequency input terminal RFIN.

The second amplification stage circuit 82 can include a transistor 830 and a transistor 840. The transistor 830 and the transistor 840 can be coupled in series. A first terminal of the transistor 830 can be coupled to the radio-frequency output terminal RFOUT, and a control terminal of the transistor 840 can be coupled to the radio-frequency input terminal RFIN. The first amplification stage circuit 81 and the second amplification stage circuit 82 can be coupled in parallel. In other words, a terminal N811 of the first amplification stage circuit 81 can be coupled to a terminal N821 of the second amplification stage circuit 82, and a terminal N812 of the first amplification stage circuit 81 can be coupled to a terminal N822 of the second amplification stage circuit 82. The switch 83 can include a first terminal and a second terminal, where the first terminal can be coupled to a node N813 between the transistor 810 and the transistor 820, and the second terminal can be coupled to a node N823 between the transistor 830 and the transistor 840. The operations and functions of the first amplification stage circuit 81, the second amplification stage circuit 82, the switch 83, and the transistors 810, 820, 830 and 840 can be similar to that of the first amplification stage circuit 110, the second amplification stage circuit 120 and the transistors 220, 250, 230, 240 and 210 in FIG. 3, so it is not repeatedly described.

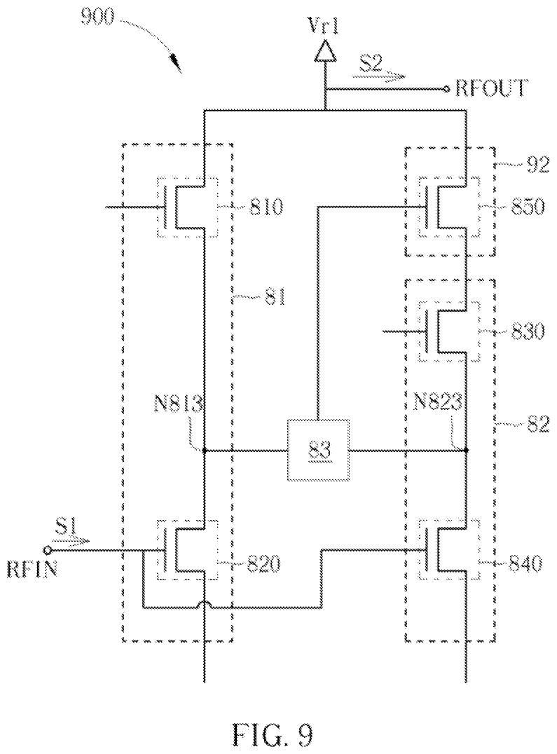

FIG. 9 illustrates an amplification circuit 900 according to another embodiment. The amplification circuit 900 can be similar to the amplification circuit 800. However, the amplification circuit 900 can further include a switching circuit 92. The switching circuit 92 can include a transistor 850, and the transistor 850 and the second amplification stage circuit 82 can be coupled in series.

As shown in FIG. 9, the switch 83 can further include a control terminal coupled to the switching circuit 92. When the transistor 850 of the switching circuit 92 is turned on, the switch 83, the transistor 830 and the transistor 840 can be turned on. At this time, voltages of the node N813 and the node 823 can be equal, improving the linearity of the circuit and improving the quality of transceiving signals. When the second amplification stage circuit 82 is disabled, the node N823 can be a high impedance node. The operations and functions of the first amplification stage circuit 81, the second amplification stage circuit 82, the switch 83 and the transistors 810, 820, 830, 840 and 850 can be similar to that of the first amplification stage circuit 110, the second amplification stage circuit 120 and the transistors 250, 230, 240, 210 and 260 in FIG. 4, and it is not repeatedly described.

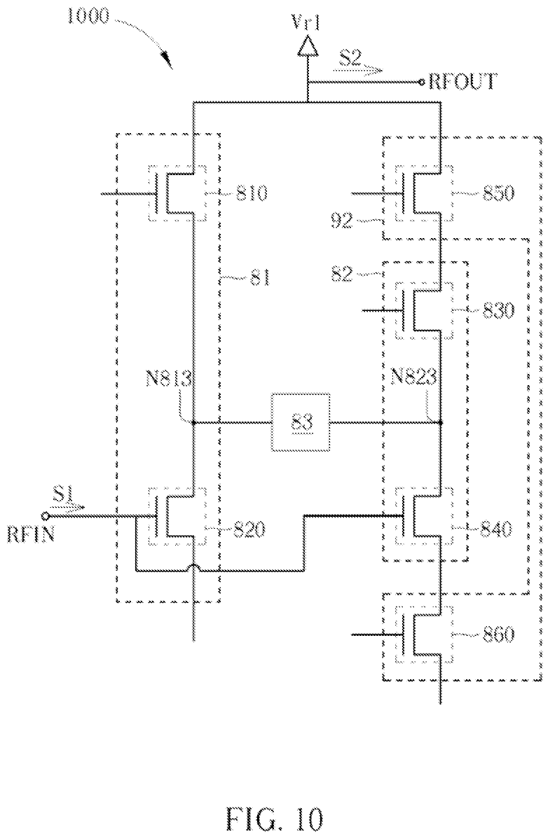

FIG. 10 illustrates an amplification circuit 1000 according to an embodiment. Compared with the amplification circuit 900, the switching circuit 92 of the amplification circuit 1000 can further include a transistor 860. The transistor 860 and the second amplification stage circuit 82 can be coupled in series, and the transistor 830 and the transistor 840 can be coupled between the transistor 850 and the transistor 860. FIG. 9 and FIG. 10 are examples, and embodiments are not limited thereto. According to another embodiment, the switching circuit 92 can include the transistor 860 but not the transistor 850. In FIG. 9 and FIG. 10, when the second amplification stage circuit 82 is disabled, the switching circuit 92 can be disabled. The operations and functions of the first amplification stage circuit 81, the second amplification stage circuit 82, the switch 83 and the transistors 810, 820, 830, 840, 850 and 860 can be similar to that of the first amplification stage circuit 110, the second amplification stage circuit 120 and the transistors 220, 250, 230, 240, 210, 260 and 270, and it is not repeatedly described.

In FIG. 8, FIG. 9 and FIG. 10, when the transistor 810 and the transistor 820 are turned on, and the transistor 830 and the transistor 840 are turned off, the amplification circuit 800, the amplification circuit 900 and the amplification circuit 1000 can be in the low current mode. When the transistor 810, the transistor 820, the transistor 830 and the transistor 840 are turned on, the amplification circuit 800, the amplification circuit 900 and the amplification circuit 1000 can be in the high current mode. When the radio-frequency output terminal RFOUT is coupled to different loads, the amplification circuit can be switched to the low current mode or the high current mode for dealing with the loads. For example, when the radio-frequency output terminal RFOUT is coupled to a lower load, the low current mode can be used. When the radio-frequency output terminal RFOUT is coupled to a higher load, the high current mode can be used. In FIG. 8 to FIG. 10, control terminals of the transistors 810, 820, 830, 840, 850 and 860 can receive DC bias signals respectively for turning on and turning off the transistors.

In summary, by using the amplification circuit 100, 200, 300, 400, 500, 600, 700, 800, 900 and/or 1000, the voltage difference of the nodes of two amplification stage circuits is reduced, so the operation timings of the two amplification stage circuits can match one another. As a result, unwanted dynamic error vector magnitude (DEVM) is reduced, the impact of history effect is reduced, the linearity of the circuit is improved, and the quality of transceiving signals is improved.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An amplification circuit comprising:
a radio-frequency input terminal configured to receive a radio-frequency signal;
a radio-frequency output terminal configured to output an amplified radio-frequency signal;
a first amplification stage circuit comprising a first terminal coupled to the radio-frequency input terminal, a second terminal coupled to the radio-frequency output terminal, and a third terminal;
a second amplification stage circuit comprising a first terminal coupled to the radio-frequency input terminal, a second terminal coupled to the radio-frequency output terminal, an internal node, and a third terminal coupled to the internal node; and
a variable impedance path coupled to the internal node, and comprising a first terminal coupled to the third terminal of the first amplification stage circuit, and a second terminal coupled to the third terminal of the second amplification stage circuit;
wherein the variable impedance path has a low impedance when the variable impedance path is enabled, and the variable impedance path has a high impedance and the internal node is a high impedance node when the variable impedance path is disabled.

2. The amplification circuit of claim 1, wherein:
the second amplification stage circuit further comprises a first transistor; and
the variable impedance path further comprises a second transistor coupled to a first terminal of the first transistor.

3. The amplification circuit of claim 2, wherein:
the first amplification stage circuit further comprises a third transistor; and
the second transistor of the variable impedance path is further coupled to a first terminal of the third transistor.

4. The amplification circuit of claim 1, wherein:
the second amplification stage circuit further comprises a first transistor and a fourth transistor;
the first transistor and the fourth transistor are coupled in series;
the first transistor and the fourth transistor are turned on when the second amplification stage circuit is enabled; and
the first transistor and the fourth transistor are turned off when the second amplification stage circuit is disabled.

5. The amplification circuit of claim 4, wherein:
the first amplification stage circuit further comprises a third transistor and a fifth transistor;
the third transistor and the fifth transistor are coupled in series; and
the third transistor and the fifth transistor are turned on when the first amplification stage circuit is enabled.

6. The amplification circuit of claim 5, wherein the radio-frequency input terminal is coupled to a control terminal of the first transistor and a control terminal of the third transistor.

7. The amplification circuit of claim 5, wherein:
when the radio-frequency output terminal is coupled to a first load, the second amplification stage circuit is enabled; and
when the radio-frequency output terminal is coupled to a second load different from the first load, the second amplification stage circuit is disabled.

8. The amplification circuit of claim 5, wherein a size of the fourth transistor and a size of the fifth transistor are different.

9. The amplification circuit of claim 5, wherein:
the variable impedance path further comprises a second transistor; and
the second transistor comprises a first terminal coupled to a node between the third transistor and the fifth transistor, and a second terminal coupled to a node between the first transistor and the fourth transistor.

10. The amplification circuit of claim 4, wherein:
the variable impedance path further comprises a second transistor;
the second transistor is turned on when the variable impedance path is enabled; and
the second transistor is turned off when the variable impedance path is disabled.

11. The amplification circuit of claim 4, wherein:
the second amplification stage circuit further comprises a sixth transistor;
the sixth transistor and the fourth transistor are coupled in series;
the fourth transistor is coupled between the first transistor and the sixth transistor;
the sixth transistor is turned on when the second amplification stage circuit is enabled; and
the sixth transistor is turned off when the second amplification stage circuit is disabled.

12. The amplification circuit of claim 4, wherein:
the second amplification stage circuit further comprises a seventh transistor;
the seventh transistor and the first transistor are coupled in series;
the first transistor is coupled between the fourth transistor and the seventh transistor;
the seventh transistor is turned on when the second amplification stage circuit is enabled; and
the seventh transistor is turned off when the second amplification stage circuit is disabled.

13. The amplification circuit of claim 4, wherein:
the second amplification stage circuit further comprises a sixth transistor and a seventh transistor;
the sixth transistor and the fourth transistor are coupled in series;
the seventh transistor and the first transistor are coupled in series;
the first transistor and fourth transistor is coupled between the sixth transistor and the seventh transistor;
the sixth transistor and the seventh transistor are turned on when the second amplification stage circuit is enabled; and
the sixth transistor and the seventh transistor are turned off when the second amplification stage circuit is disabled.

14. The amplification circuit of claim 1, further comprising an eighth transistor and an inductor coupled in parallel, wherein:
the first amplification stage circuit further comprises a fourth terminal;
the second amplification stage circuit further comprises a fourth terminal;
the eighth transistor comprises a first terminal coupled to the fourth terminal of the first amplification stage circuit and the fourth terminal of the second amplification stage circuit, and a second terminal configured to receive a predetermined voltage;
the eighth transistor is in one state of an ON state and an OFF state when the second amplification stage circuit is enabled; and
the eighth transistor is in the other one state of the ON state and the OFF state when the second amplification stage circuit is disabled.

15. An amplification circuit comprising:
a radio-frequency input terminal configured to receive a radio-frequency signal;
a radio-frequency output terminal configured to output an amplified radio-frequency signal;
a first amplification stage circuit comprising a first transistor and a second transistor coupled in series, wherein a first terminal of the first transistor is coupled to the radio-frequency output terminal, and a control terminal of the second transistor is coupled to the radio-frequency input terminal;
a second amplification stage circuit comprising a third transistor and a fourth transistor coupled in series, wherein a first terminal of the third transistor is coupled to the radio-frequency output terminal, and a control terminal of the fourth transistor is coupled to the radio-frequency input terminal; and
a switch comprising a first terminal coupled to a node between the first transistor and the second transistor, and a second terminal coupled to a node between the third transistor and the fourth transistor.

16. The amplification circuit of claim 15 further comprising:
a switching circuit comprising a fifth transistor, wherein the fifth transistor and the second amplification stage circuit are coupled in series.

17. The amplification circuit of claim 16, wherein the switch further comprises a control terminal coupled to the switching circuit.

18. The amplification circuit of claim 17, wherein when the switching circuit is turned on, the switch, the third transistor and the fourth transistor are turned on.

19. The amplification circuit of claim 16, wherein the switching circuit further comprises a sixth transistor, wherein the sixth transistor and the second amplification stage circuit are coupled in series, and the third transistor and the fourth transistor are coupled between the fifth transistor and the sixth transistor.

20. The amplification circuit of claim 15, wherein:
the amplification circuit is in a low current mode when the first transistor and the second transistor are turned on, and the third transistor and the fourth transistor are turned off, and
the amplification circuit is in a high current mode when the first transistor and the second transistor, the third transistor and the fourth transistor are turned on.
